(19) United States
(12) Patent Application Publication
(10) Pub. No.: US 2026/0150464 A1
(43) Pub. Date: May 28, 2026

(54) DISPLAY PANEL, DISPLAY DEVICE INCLUDING THE SAME, AND METHOD FOR MANUFACTURING THE DISPLAY DEVICE

(71) Applicant: Korea Advanced Institute of Science and Technology, Daejeon (KR)

(72) Inventors: Kyung Cheol Choi, Daejeon (KR); Jaehyeock Chang, Daejeon (KR)

(21) Appl. No.: 19/396,194

(22) Filed: Nov. 20, 2025

(30) Foreign Application Priority Data
Nov. 28, 2024 (KR) 10-2024-0173617

(51) Int. Cl. H10H 29/49; H10H 29/01

(52) U.S. Cl. CPC H10H 29/49; H10H 29/012

(57) ABSTRACT

A display panel includes a substrate, and a plurality of light-emission units. The substrate includes a plurality of upper units arranged two-dimensionally on a plane and separated by upper trenches, a plurality of lower units and arranged two-dimensionally on a plane and separated by lower trenches, and a plurality of pillar units connecting one of the plurality of upper units and one of the plurality of lower units in a thickness direction. The plurality of light-emission units are disposed on the plurality of upper units and arranged two-dimensionally. Each of the plurality of upper units is connected to at least two pillar units, each of the plurality of lower units is connected to at least two pillar units, and each of pillar units extending from one upper unit among the plurality of upper units is connected to different lower units among the plurality of lower units.

### CROSS-REFERENCE TO RELATED APPLICATION

The present application claims priority to and the benefit of Korean Patent Application No. 10-2024-0173617, filed on November 28, 2024, in the Korean Intellectual Property Office, and all the benefits accruing therefrom under 35 U.S.C § 119, the contents of which are incorporated herein in its entirety by reference.

### BACKGROUND

### 1. Technical Field

The present disclosure relates to a display panel, a display device including the same, and a method for manufacturing a display device. More particularly, the present disclosure relates to a flexible display panel, a display device including the same, and a method for manufacturing a display device.

### 2. Description of the Related Art

Electronic devices, such as a smartphone, a digital camera, a laptop computer, a navigation, and a smart television, that provide images to users include a display device. The display device generates an image and provides it to the user through a display screen. Recently, with advances in display device technology, various types of display devices have been developed. For example, a variety of flexible display devise that can be curved, folded, or rolled have been developed. Flexible display devices, which can be deformed into various shapes, are easy to carry and improve user convenience.

Currently, flexible display devices can be folded along a specific folding axis or rolled into a cylindrical shape. However, to further improve the portability and user experience of display devices, a variable form that can be more broadly applied to, for example, human bodies, buildings, and vehicles, is required. For example, it may be necessary for a display device to conform to complex curves, such as spherical or saddle-shaped surfaces. Furthermore, considerations regarding the structure of the display panel, signal wiring, and arrangement of light-emitting diodes are required to realize such complex curved surfaces.

### SUMMARY

The present disclosure is to provide a display panel capable of being deformed into various and complex curved surfaces, a display device including the same, and a method for manufacturing a display device.

In addition, the present disclosure is to provide a display panel that reduces stress on a light-emission unit even under various deformations, prevents disconnection of, for example, signal lines, and thereby ensures stable display performance, a display device including the same, and a method for manufacturing a display device.

A display panel according to one embodiment of the present disclosure includes a substrate and a plurality of light-emission units. The substrate includes a plurality of upper units arranged two-dimensionally on a plane and separated by upper trenches, a plurality of lower units arranged two-dimensionally on a plane and separated by lower trenches, and a plurality of pillar units connecting, in a thickness direction, one of the plurality of upper units and one of the plurality of lower units. The plurality of light-emission units are disposed on the plurality of upper units and arranged two-dimensionally. Each of the plurality of upper units is connected to at least two pillar units, and each of the plurality of lower units is connected to at least two pillar units. The pillar units extending from one upper unit among the plurality of upper units are respectively connected to different lower units among the plurality of lower units.

In one embodiment, the upper trenches overlaps with the plurality of lower units while not overlapping with the plurality of upper units and the plurality of pillar units in a planar view. The lower trenches overlaps with the plurality of upper units while not overlapping with the plurality of lower units and the plurality of pillar units in a planar view.

In one embodiment, each of the plurality of upper units is partitioned in a second direction intersecting with a first direction by first upper trenches extending in the first direction, and is partitioned in the first direction by second upper trenches extending in the second direction. Each of the plurality of lower units is partitioned in the second direction by first lower trenches extending in the first direction, and is partitioned in the first direction by second lower trenches extending in the second direction. In one embodiment, the first upper trenches do not overlap with the first lower trenches, and the second upper trenches do not overlap with the second lower trenches.

In one embodiment, each of the plurality of upper units overlaps with at least two lower units among the plurality of lower units, and at least two pillar units among the plurality of pillar units, and is connected to the overlapping lower units through the overlapping pillar units. In one embodiment, each of the plurality of upper units is connected to four lower units through four pillar units, and each of the plurality of lower units is connected to four upper units through four pillar units.

In one embodiment, respective cross-sectional areas of the plurality of pillar units in a planar view are smaller than an area of one upper unit divided by a number of pillar units connected to the upper units. In one embodiment, respective thicknesses of the plurality of pillar units are greater than thicknesses of the plurality of upper units or thicknesses of the plurality of lower units.

In one embodiment, a plurality of contact holes penetrating the plurality of pillar units, respectively, in thickness directions are formed, and the plurality of contact holes further penetrate the plurality of upper units and the plurality of lower units overlapping in thickness directions. In one embodiment, lines electrically connected to the plurality of light-emission units are provided in the plurality of contact holes, and the lines provided in the plurality of contact holes are electrically connected through lower surfaces of the plurality of lower units.

In one embodiment, the display panel further includes scan lines provided in first contact holes among the plurality of contact holes and electrically connected to light-emission units arranged in the first direction, data lines provided in second contact holes different from the first contact holes among the plurality of contact holes and electrically connected to light-emission units arranged in the second direction intersecting with the first direction.

In one embodiment, scan lines extending in the first direction are disposed on lower surfaces of the first lower units, where the first contact holes are formed, among the plurality of lower units, data lines extending in the second direction are disposed on lower surfaces of the second lower units, where the second contact holes are formed, among the plurality of lower units, and the first lower units and the second lower units are alternatingly arranged in the first direction and the second direction.

In one embodiment, the display panel further includes power supply lines provided in third contact holes different from the first contact holes and the second contact holes among the plurality of contact holes and electrically connected to the light-emission units arranged in the first direction or the second direction. In one embodiment, scan lines extending in the first direction, and data lines extending in the second direction are disposed on lower surfaces of the plurality of lower units, and the display panel further includes a plurality of insulation patterns disposed between the scan lines and the data lines and overlapping with the plurality of lower units.

The display device according to one embodiment of the present disclosure includes a display panel with pixels connected to a scan line and a data line and arranged two-dimensionally, and a driving circuit configured to control operation of pixels through the scan line and the data line to display an image. The display panel includes a substrate including a plurality of upper units arranged two-dimensionally on a plane and separated by upper trenches, a plurality of lower units arranged two-dimensionally on a plane and separated by lower trenches, and a plurality of pillar units connecting one of the plurality of upper units and one of the plurality of lower units in a thickness direction, and a plurality of light-emission units disposed on the plurality of upper units and corresponding to pixels. Each of the plurality of upper units is connected to at least two pillar units, each of the plurality of lower units is connected to at least two pillar units, and each of pillar units extending from one upper unit among the plurality of upper units is connected to different lower units among the plurality of lower units.

In one embodiment, a plurality of contact holes respectively penetrating the plurality of pillar units in thickness directions are formed on the substrate, and the plurality of contact holes further penetrate the plurality of upper units and the plurality of lower units facing each other in a thickness direction. A scan line is provided in first contact holes among the plurality of contact holes, and a data line is provided to the second contact holes among the plurality of contact holes.

In one embodiment, the driving circuit is configured to control a potential between the data line and the scan line to activate pixels for displaying an image. In one embodiment, the driving circuit includes a data driver configured to output a data signal to the pixels through the data line, a scan driver configured to sequentially activate the pixels to display an image according to the data signal through a scan line, and a timing controller configured to control the data driver and the scan driver.

A method for manufacturing a display device according to one embodiment of the present disclosure includes providing a substrate including a plurality of upper units arranged two-dimensionally on a plane and separated by upper trenches, a plurality of lower units arranged two-dimensionally on a plane and separated by lower trenches, and a plurality of pillar units connecting one of the plurality of upper units and one of the plurality of lower units in a thickness direction and having a plurality of contact holes formed therein; forming signal lines on the plurality of contact holes, the plurality of upper units, and the plurality of lower units; and forming a plurality of light-emission units on the signal lines and the plurality of upper units. Each of the plurality of upper units is connected to at least two pillar units, each of the plurality of lower units is connected to at least two pillar units, and each of pillar units extending from one upper unit among the plurality of upper units are respectively connected to different lower units among the plurality of lower units. The plurality of contact holes further penetrate the plurality of upper units and the plurality of lower units overlapping in the thickness direction.

In one embodiment, the method for manufacturing a display device further includes, after the forming the signal lines, forming a first conductive layer electrically connected to at least a portion of the signal lines; forming an activation layer overlapping with at least a portion of the first conductive layer; forming a first insulating layer covering the activation layer; forming a second conductive layer overlapping with the first insulating layer and the activation layer and electrically connected to at least a portion of the signal lines; and forming a second insulating layer on the first conductive layer, the activation layer, the first insulating layer, and the second conductive layer.

According to one embodiment of the present disclosure, a display panel, a display device including the same, and a method for manufacturing a display device can be deformed to complex curved surfaces through a substrate structure separated by upper trenches and lower trenches.

According to one embodiment of the present disclosure, a display panel, a display device including the same, and a method for manufacturing a display device can perform stable display functions even under various deformations by arranging signal lines and light-emission units through contact holes in a unique substrate structure.

### BRIEF DESCRIPTION OF THE DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1 is a perspective view of a display panel according to one embodiment of the present disclosure;

FIG. 2 is an exemplary perspective view of the substrate shown in FIG. 1;

FIG. 3 is an enlarged view of the AA area corresponding to a planar shape of the substrate shown in FIG. 2;

FIG. 4 is an enlarged view of the BB area corresponding to a side surface shape of the substrate shown in FIG. 2;

FIG. 5 is a perspective view of a partial area of a substrate corresponding to a unit pixel of the substrate shown in FIG. 2;

FIG. 6 is an illustration to explain a relaxation motion of the substrate shown in FIG. 1;

FIG. 7 is an illustration to explain a contraction motion of the substrate shown in FIG. 1;

FIG. 8 is an illustration to explain a bending motion of the substrate shown in FIG. 1;

FIG. 9 is an exemplary block diagram of a display device including the display panel shown in FIG. 1;

FIG. 10 is an exemplary circuit diagram of the pixel shown in FIG. 9;

FIG. 11 is an exemplary front view of the display panel shown in FIG. 9;

FIG. 12 is an exemplary rear view of the display panel shown in FIG. 9;

FIG. 13 is an exemplary perspective view of the pixel shown in FIG. 9;

FIG. 14 is an exemplary block diagram of a display device including the display panel shown in FIG. 1;

FIG. 15 is an exemplary circuit diagram of the pixel shown in FIG. 14

FIG. 16 is an exemplary front view of the display panel shown in FIG. 14;

FIG. 17 is an exemplary rear view of the display panel shown in FIG. 14; and

FIG. 18A through FIG. 18G are illustrations to explain a method for manufacturing the display device shown in FIG. 14.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

Hereinafter, certain embodiments of the present disclosure will be described in more detail with reference to the accompanying drawings. In the drawings, the proportions and dimensions of components may be exaggerated for clarity and ease of explanation.

Any expressions such as “comprise” or “include” are intended to specify the presence of features, integers, steps, operations, elements, components, or combinations thereof stated in the specification, and shall not be construed to preclude any possibility of presence or addition of one or more other features, integers, steps, operations, elements, components, or combinations thereof.

Furthermore, when a component is described as being “on” another component, it may be located above or below the other component and does not necessarily imply being positioned on the upper side in the direction of gravity.

When a component is described as being “connected” or “coupled” to another component, it may be directly connected or coupled to the other component or indirectly connected or coupled via another component.

Terms such as “first” and “second” may be used when referring to components, but these terms are intended only for distinguishing one component from another and do not imply any limitation on the nature, order, or sequence of the components.

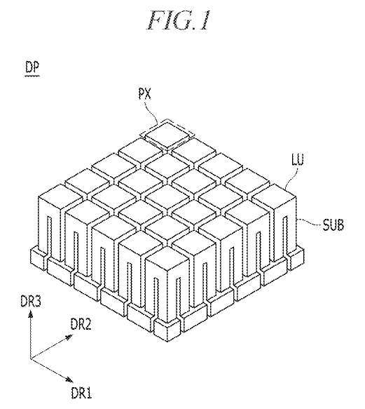

FIG. 1 is a perspective view of a display panel according to one embodiment of the present disclosure. Referring to FIG. 1, the display panel DP includes a substrate SUB and light-emission units LU. The display panel DP is to be understood as an element included in a display device, or an electronic device having a display function.

To explain a display panel DP according to the present disclosure, first through third directions DR1 through DR3 are defined. The display panel DP is formed to include pixels PX on a plane defined by the first direction DR1 and the second direction DR2. The third direction DR3 is defined as a thickness direction of the display device, and the first through third directions DR1 through DR3 may be perpendicular to one another.

The substrate SUB is formed to physically stably support structures disposed on its upper portion. The substrate SUB may be an insulator. The substrate SUB may have a unique structure capable of variable deformation in various directions, such as contraction, relaxation, and bending. The substrate SUB may have a structure capable of deformation to a complex multi-curved surface, and a detailed structure thereof will be described later.

The substrate SUB may include an elastic material capable of various deformations. In one embodiment, the substrate SUB may include a photolithography-processable material, such as Su-8 or a UV-curable resin. In one embodiment, the substrate SUB may be a flexible substrate including a material, such as polyethylene terephthalate (PET), polyimide (PI), polyetherethereketone (PEEK), or colorless polyimide (CPI). In one embodiment, the substrate SUB may include a polymer substrate including a material, such as polydimethylsiloxane (PDMS), polyurethane (PU), or thermoplastic polyurethane (TPU). The substrate SUB may include at least one of the described materials, or a combination thereof. In one embodiment, the substrate SUB may be formed, for example, through a photolithography process, a wet or dry etching process, a laser cutting process, a drilling process, a computer numerical control (CNC) process.

The light-emission units LU may be disposed on the substrate SUB. The light-emission units LU are arranged two-dimensionally on a plane defined by a first direction DR1 and a second direction DR2. The substrate SUB may have a structure with a plurality of trenches to form a multiple curved surfaces, and the light-emission units LU may each be disposed on one area among specific areas of the substrate SUB partitioned by the plurality of trenches. One light-emission unit LU may correspond to one pixel PX, and one light-emission unit LU corresponding to one pixel PX may be disposed in a partitioned area. However, the present disclosure is not limited thereto, and two or more light-emission units LU may be disposed in a partitioned area.

The light-emission unit LU includes a light-emitting material. In one embodiment, the light-emission unit LU may include an organic material including a fluorescence or phosphorescence material emitting light, for example, of red color, green color, and blue color. The light-emission unit LU may be a light-emitting diode, but the present disclosure is not limited thereto. For example, the light-emission unit LU may be a micro light-emitting diode, a quantum dot light-emitting diode, or an inorganic light-emitting diode.

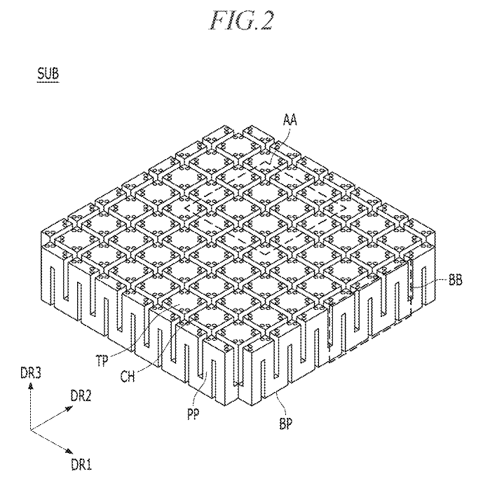

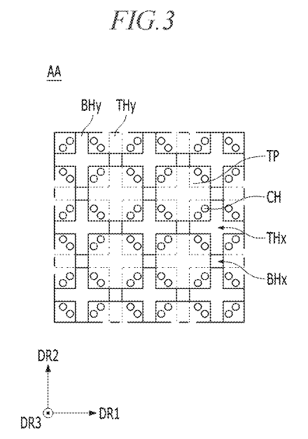

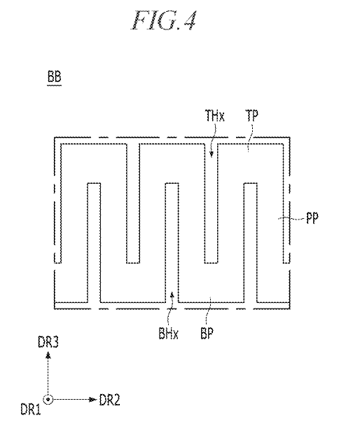

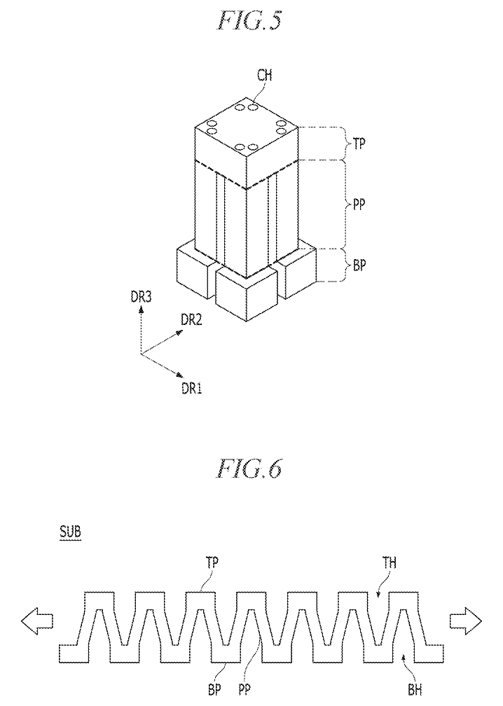

FIG. 2 is an exemplary perspective view of the substrate shown in FIG. 1. FIG. 3 is an enlarged view of the AA area corresponding to a planar shape of the substrate shown in FIG. 2. FIG. 4 is an enlarged view of the BB area corresponding to a shape of a side surface of the substrate shown in FIG. 2. FIG. 5 is a perspective view of a partial area of the substrate corresponding to a unit pixel of the substrate shown in FIG. 2. Referring to FIG. 2 through FIG. 5, the substrate SUB includes a plurality of upper units TP, a plurality of pillar units PP, and a plurality of lower units BP.

Referring to FIG. 2, the plurality of upper units TP are arranged two-dimensionally on a plane defined by the first direction DR1 and the second direction DR2. The plurality of light-emission units LU are disposed on the plurality of upper units TP. One light-emission unit LU may be disposed on one upper unit TP to form a pixel PX. However, the present disclosure is not limited thereto, and two or more light-emission units LU may be disposed on one upper unit TP. Each of the plurality of upper units TP may be separated from one another to form an island-like structure. The plurality of light-emission units LU may be stably supported by the plurality of upper units even under various deformation of the substrate SUB, and mechanical stress applied to the plurality of light-emission units LU may be reduced.

Referring to FIG. 3, each of the plurality of upper units TP is separated from one another through first upper trenches THx and second upper trenches THy. The first upper trenches THx extend in the first direction DR1. Each of the first upper trenches THx may be spaced apart from one another in the second direction DR2 to partition the plurality of upper units TP in the second direction DR2. The second upper trenches THy extend in the second direction DR2. Each of the second upper trenches Thy may be spaced apart from one another in the first direction DR1 to partition the plurality of upper units TP in the first direction DR1.

The plurality of lower units BP, like the plurality of upper units TP, are arranged two-dimensionally on a plane defined by the first direction DR1 and the second direction DR2. The plurality of lower units BP may each be separated from one another to form an island-like structure. The plurality of lower units BP may each be separated from one another through first lower trenches BHx and second lower trenches BHy. The first lower trenches BHx extend in the first direction DR1. The first lower trenches BHx may each be separated in the second direction DR2 to partition the plurality of lower units BP in the second direction DR2. The second lower trenches BHy extend in the second direction DR2. The second lower trenches BHy may each be spaced apart from one another in the first direction DR1 to partition the plurality of upper units TP in the first direction DR1.

Positions of the plurality of upper units TP and positions of the plurality of lower units BP may be arranged to be staggered on a plane. For example, one upper unit TP may overlap with four lower units BP. The upper trenches THx, THy may overlap with the plurality of lower units BP while not overlapping with the plurality of upper units TP. The lower trenches BHx, BHy may overlap with the plurality of upper units TP while not overlapping with the plurality of lower units BP. The first upper trenches THx may not overlap with the first lower trenches BHx. The second upper trenches THy may not overlap with the second lower trenches BHy.

The plurality of upper units TP may each have a quadrilateral shape by the upper trenches THx, THy. The plurality of lower units BP may each have a quadrilateral shape by the lower trenches BHx, BHy. However, the present disclosure is not limited thereto, and the plurality of upper units TP and the plurality of lower units BP may have various shapes, such as a triangular shape or a hexagonal shape, and in case that they have quadrilateral shapes, the shapes are not limited to a square shape and may include various shapes, such as a rectangle or a parallelogram.

Referring to FIG. 4, the plurality of pillar units PP may connect the plurality of upper units TP and the plurality of lower units BP in the third direction DR3. The upper trenches THx, THy and the lower trenches BHx, BHy may extend to side surfaces of the plurality of pillar units PP to separate each of the plurality of pillar units PP. Accordingly, the plurality of pillar units PP are arranged two-dimensionally on a plane defined by the first direction DR1 and the second direction DR2.

One pillar unit PP connects one upper unit TP and one lower unit BP overlapping in the third direction DR3. One upper unit TP is connected to at least two pillar units PP, and one lower unit BP is connected to at least two pillar units PP. Accordingly, the plurality of separated upper units TP and the plurality of separated lower units BP may be integrated.

Referring to FIG. 5, the pillar units PP extending from one upper unit TP are respectively connected to different lower units BP. In one embodiment, one upper unit TP may be connected to four pillar units PP, and the four pillar units PP may be connected to different lower units BP. In this case, the substrate SUB may be flexibly deformed in upward, downward, leftward, and rightward directions. However, the present disclosure is not limited thereto, and one upper unit TP may be connected to various numbers, such as two, three or six, of pillar units PP.

A length of one side of one upper unit TP and one lower unit BP in the first direction DR1 or the second direction DR2 is not limited and may exemplarily be 10 mm to 10 μm. A cross-sectional area of one pillar unit PP may be smaller than an area of one upper unit TP or one lower unit BP divided by a number (e.g., 4) of pillar units PP connected to one upper unit TP. In one embodiment, a length of one side of one pillar unit PP may be 1% to 50% of a length of one side of one upper unit TP.

In one embodiment, a thickness of the pillar unit PP in the third direction DR3 may be greater than a thickness of the upper unit TP or the lower unit BP and exemplarily be 1 to 100 times, but the present disclosure is not limited thereto. In addition, in order to reduce deformation of the display panel DP, a thickness of the pillar unit PP in the third direction DR3 may be smaller than a thickness of the upper unit TP or the lower unit BP.

The substrate SUB may have a plurality of contact holes CH formed therein, the plurality of contact holes penetrating the plurality of pillar units PP in the third direction DR3. The plurality of contact holes CH may be formed to further penetrate the upper unit TP and the lower unit BP overlapping in the third direction DR3. Lines, such as a scan line or a data line, to drive the light-emitting units LU, which will be described later, may be provided through the plurality of contact holes CH. Accordingly, disconnection of the lines due to deformation of the substrate SUB may be prevented to allow stable display functionality.

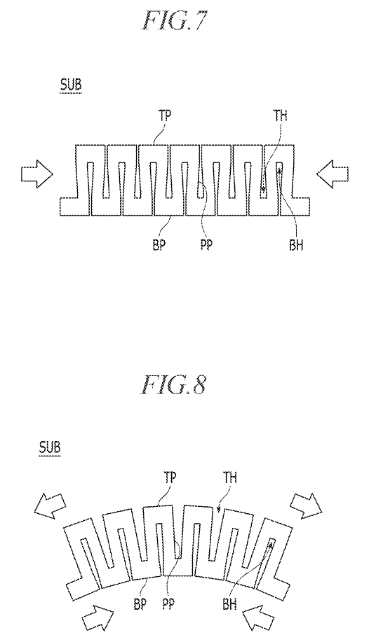

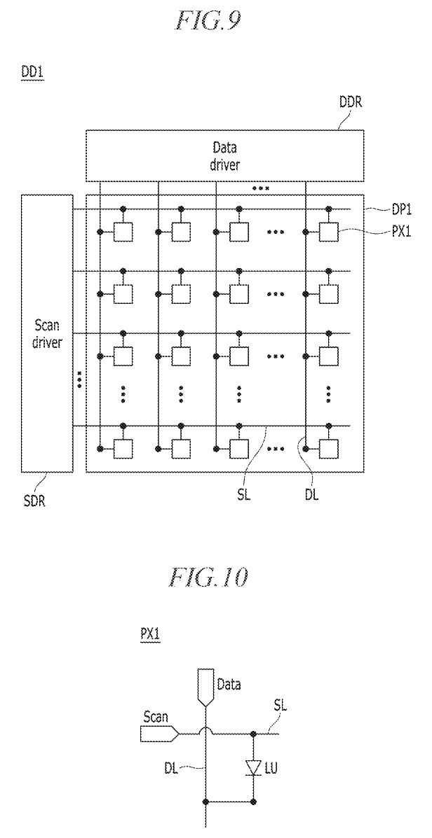

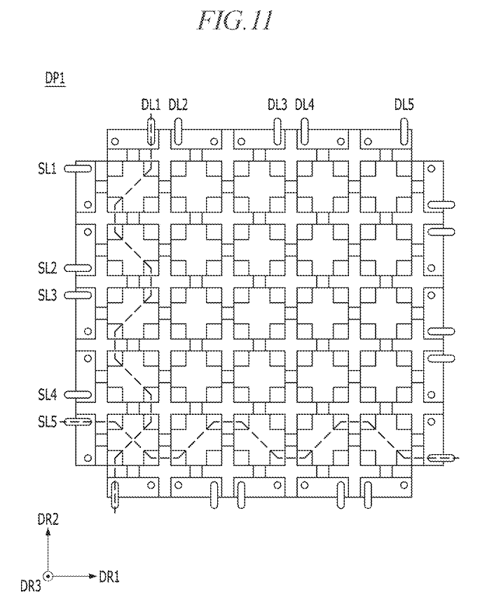

FIG. 6 is an illustration to explain a relaxation motion of the substrate shown in FIG. 1. FIG. 7 is an illustration to explain a contraction motion of the substrate shown in FIG. 1. FIG. 8 is an illustration to explain a bending motion of the substrate shown in FIG. 1. Referring to FIG. 6 through FIG. 8, the described unique shapes of the substrates SUB may allow formation of various curves.

Referring to FIG. 6, a tensile force may be applied to the substrate SUB in the first direction DR1 or the second direction DR2. Accordingly, widths of the upper trenches TH and the lower trenches BH may become greater. The upper trenches TH and the lower trenches BH correspond to the described upper trenches THx, THy and lower trenches BHx, BHy, respectively. The plurality of pillar units PP may be stretched, and each of the plurality of upper units TP and the plurality of lower units BP may be spaced apart from one another in a direction of application of an external force. That is, the substrate SUB may be relaxed. When the external force is removed, the substrate SUB returns to its original shape.

Referring to FIG. 7, a compressive force may be applied to the substrate SUB in the first direction DR1 or the second direction DR2. Accordingly, widths of the upper trenches TH and the lower trenches BH may become smaller. Each of the plurality of upper units TP and the plurality of the lower units BP may become closer to one another. That is, the substrate SUB may be compressed. When the external force is removed, the substrate SUB returns to its original shape.

Referring to FIG. 8, the plurality of upper units TP (conversely, the plurality of lower units BP) may be applied with a tensile force, and the plurality of lower units BP (conversely, the plurality of upper units TP) may be applied with a compressive force. Accordingly, widths of the upper trenches TH may become greater, and widths of the lower trenches BH may become smaller. Each of the plurality of upper units TP may be spaced apart from one another in a direction of application of an external force, and each of the plurality of lower units BP may become close to one another in a direction of application of an external force. That is, the substrate SUB may be bent. When the external forces are removed, the substrate SUB returns to its original shape.

In FIG. 6 to FIG. 8, the described contraction, relaxation, and bending motions of the substrate SUB may act in combination. Accordingly, flexible and stretchable display panels DP may be provided. The substrate SUB according to the present disclosure may be deformed to a curved surface with various and complex curvatures. A substrate SUB according to the present disclosure may be deformed to be applied, for example, in various environments, such as a body, a structure, or a vehicle.

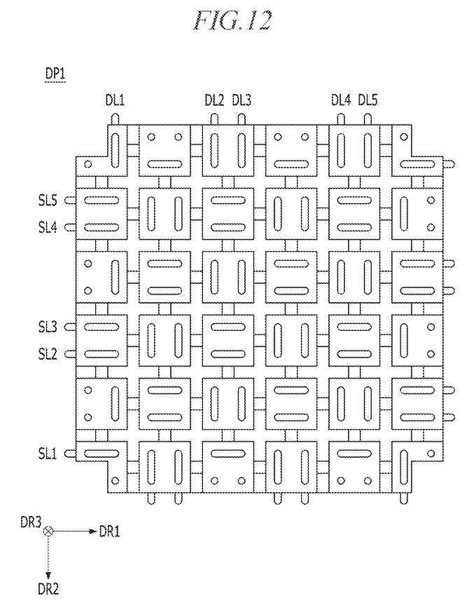

FIG. 9 is an exemplary block diagram of a display device including a display panel. Referring to FIG. 9, the display device DD1 includes a display panel DP1, a scan driver SDR, and a data driver DDR. The display panel DP1 corresponds to display panels DP explained in FIG. 1 through FIG. 8. The display panel DP1 may be deformed to have various curved surfaces through the described structure of a substrate. The scan driver SDR and the data driver DDR are to be understood as exemplary elements of the driving circuit to drive the pixels PX1.

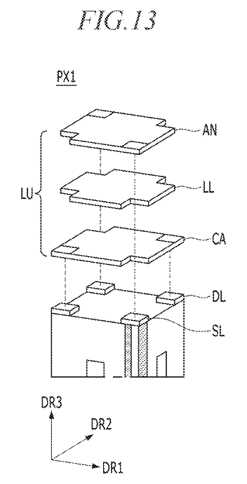

The display panel DP1 includes pixels PX1 arranged two-dimensionally on a plane. The pixels PX1 correspond to the pixels PX shown in FIG. 1. Each of the pixels PX1 is electrically connected to the scan driver SDR through the scan lines SL, and electrically connected to the data driver DDR through the data lines DL. The pixels PX1 may be operated in a passive matrix manner, and a detailed description thereof will be made with reference to FIG. 10.

The scan driver SDR may apply the scan signals to the pixels PX1 through the scan lines SL to activate the pixels PX1 in units of rows. Here, the activation refers to a state in which an emission operation corresponding to a data signal can be performed on the pixels PX1 through the data lines DL.

The data driver DDR may be configured to apply the data signal to the pixels PX1 through the data lines DL to drive the pixels PX1. Luminance of light emitted by the pixels PX1 may be determined by the data signal. Particularly, the pixels PX1 may emit light having a luminance that depends on the potential between the data lines DL and the scan lines SL electrically connected thereto. Among the pixels PX1, the pixels in the row activated by the scan driver SDR may emit light having a luminance controlled by the data driver DDR.

FIG. 10 is an exemplary circuit diagram of a pixel shown in FIG. 9. Referring to FIG. 10, the pixel PX1 includes a light-emission unit LU. The light-emission unit LU corresponds to the light-emission unit LU described in FIG. 1. The light-emission unit LU is electrically connected to the data line DL and the scan line SL. The pixel PX1 may operate in a passive driving mode without including a separate active element. Accordingly, the pixel PX1 emits light having a luminance depending on a potential between the data line DL and the scan line SL electrically connected thereto.

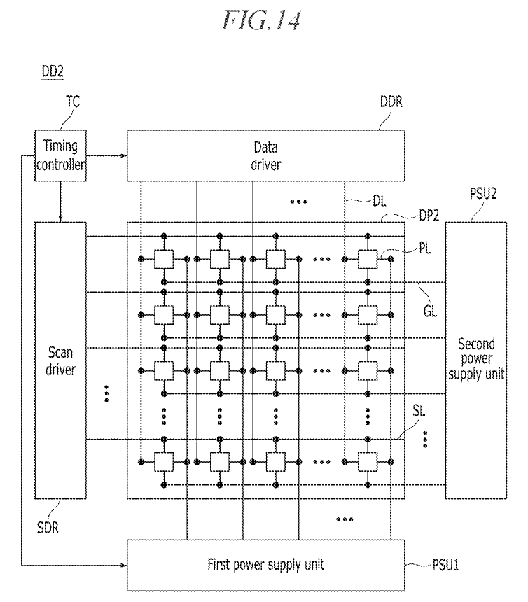

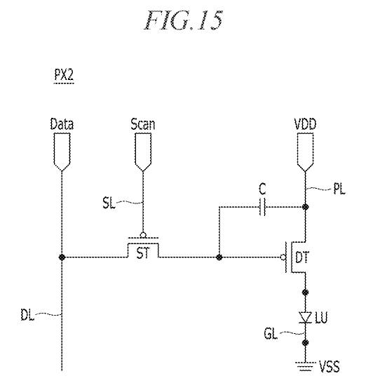

FIG. 11 is an exemplary front view of the display panel shown in FIG. 9. FIG. 12 is an exemplary rear view of the display panel shown in FIG. 9. Referring to FIG. 11 and FIG. 12, scan lines SL1 through SL5 and the data lines DL1 through DL5 are electrically connected to the pixels PX1 of the display panel DP1. The scan lines SL1 through SL5 extend in the first direction and are spaced apart from one another in the second direction DR2. The data lines DL1 through DL5 extend in the second direction DR2 and are spaced apart from one another in the first direction DR1. Shapes of the pixels PX1 and the substrate are described with references to FIG. 2 and FIG. 3, and the detailed descriptions thereof will be omitted for convenience.

Referring to FIG. 11, each of the scan lines SL1 through SL5 and the data lines DL1 through DL5 extends in the first direction DR1 or the second direction DR2 through contact holes formed in the substrate. In one embodiment, a first data line DL1 extends in the second direction DR2 through some of contact holes formed in pixels arranged in a first row. In one embodiment, a fifth scan line SL5 extends in the first direction DR1 through some of contact holes formed in pixels arranged in a fifth row.

The scan lines SL1 through SL5 and the data lines DL1 through DL5 are electrically connected to the light-emission unit on an upper surface of the upper units to extend bypassing the described lower trenches. In order to prevent paths of the scan lines SL1 through SL5 and the data lines DL1 through DL5 from overlapping, the lines formed in contact holes diagonally arranged within one pixel may be electrically connected. For example, in a pixel of a fifth row and a first column, in order to prevent paths of a first data line DL1 and a fifth scan line SL5 from overlapping, the first data line DL1 and the fifth scan line SL5 may extend through contact holes arranged on different diagonals.

Referring to FIG. 12, each of the scan lines SL1 through Sl5 and the data lines DL1 through DL5 extends in the first direction DR1 or the second direction DR2 through contact holes formed in the substrate. The scan lines SL1 through SL5 and the data lines DL1 through DL5 may be electrically connected from lower surfaces of the lower units through contact holes to extend bypassing the described upper trenches. In one embodiment, as illustrated by the dotted line in FIG. 11, a first data line DL1 may extend in the second direction DR2 along a lower surface of the lower unit. In one embodiment, as illustrated by the dotted line in FIG. 11, a fifth scan line SL5 may extend in the first direction DR1 from a lower surface of the lower unit.

The lower unit connects adjacent upper units partitioned by the upper trenches. On lower surfaces of some lower units (first lower units) among the lower units, scan lines SL1 through SL5 are disposed. On lower surfaces of other lower units (second lower units) among the lower units, data lines DL1 through DL5 are disposed. In order to prevent paths of the scan lines SL1 through SL5 and the data lines DL1 through DL5 from overlapping, the first lower units and the second lower units may be alternatingly arranged in the first direction DR1 and the second direction DR2.

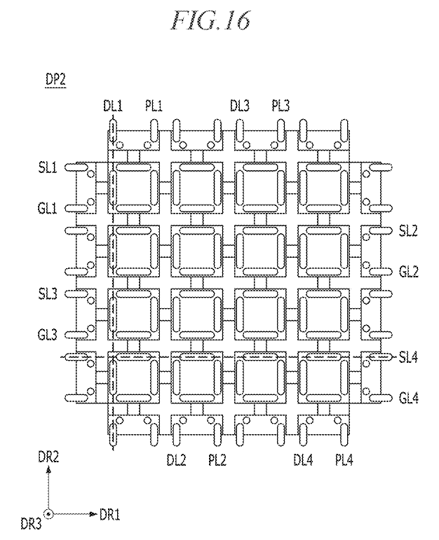

FIG. 13 is an exemplary perspective view of the pixel shown in FIG. 9. Referring to FIG. 13, the pixel PX1 includes a light-emission unit LU. The light-emission unit LU includes an anode electrode AN, a light-emission layer LL, and a cathode electrode CA. The light-emission unit LU is formed on the described upper unit. Contact holes are provided to form a data line DL and a scan line SL in the upper unit.

The light-emission layer LL is disposed on the upper unit of the described substrate. The light-emission layer LL includes a light-emitting material. In one embodiment, the light-emission layer LL may include an organic material including a fluorescence or phosphorescence material emitting light of, for example, red color, green color, and blue color.

The light-emission layer LL may include a low polymer organic material or polymer organic material.

The cathode electrode CA is disposed between the light-emission layer LL and the upper unit. The cathode electrode CA is electrically connected to the data line DL formed in the upper unit. A conductive pad may be provided for the electrical connection. The data line DL is formed in two contact holes of four contact holes diagonally disposed to each other, and the formed data line DL may be electrically connected through the cathode electrode CA. Accordingly, the data line DL may extend in the second direction DR2 without interference with the scan line SL.

The anode electrode AN is disposed on the light-emission layer LL. The anode electrode AN is electrically connected to a scan line SL formed in the upper unit. A conductive pad may be provided for the electrical connection. The scan line SL is formed in two contact holes of four contact holes diagonally disposed to each other, and the formed scan line SL may be electrically connected through the anode electrode AN. Accordingly, the scan line SL may extend in the first direction DR1 without interference with the data line DL.

Through the embodiments described in FIG. 11 through FIG. 13, in a structure where a front surface and a rear surface of the substrate are partitioned by islands, wiring connections may be achieved in which paths of the data line and the scan line do not overlap, and a number of the contact holes is minimized.

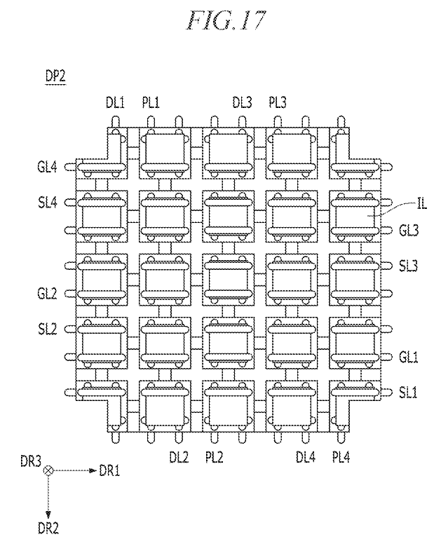

FIG. 14 is an exemplary block diagram of a display device including the display panel shown in FIG. 1. Referring to FIG. 14, the display device DD2 includes a display panel DP2, a scan driver SDR and a data driver DDR, a first power supply unit PSU1, a second power supply unit PSU2, and a timing controller TC. The display panel DP2 corresponds to the display panel DP described with references to FIG. 1 through FIG. 8. The scan driver SDR and the data driver DDR, the first power supply unit PSU1, the second power supply unit PSU2, and the timing controller TC are to be understood as exemplary elements of a driving circuit to drive the pixels PX2.

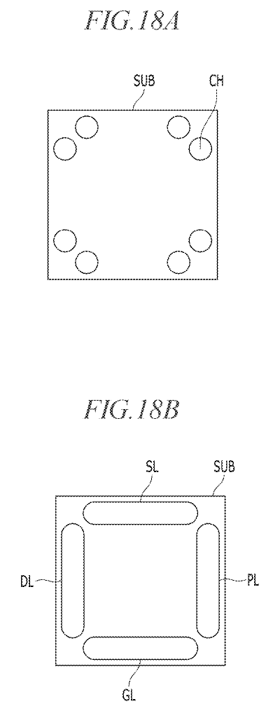

The display panel DP2 includes pixels PX2 two-dimensionally arranged on a plane. The pixels PX2 corresponds to the pixels PX shown in FIG. 1. Each of the pixels PX2 is electrically connected to the scan driver SDR through the scan lines SL and electrically connected to the data driver DDR through the data lines DL. Each of the pixels PX2 is electrically connected to the first and second power supply units PSU1, PSU2 through power lines PL and ground lines GL. The pixels PX2 may operate in an active matrix mode, and a detailed description thereof will be made with reference to FIG. 15.

The timing controller TC is configured to control operations of the scan driver SDR, the data driver DDR, and the power supply unit PSU. The timing controller TC is configured to receive an image signal and a control signal. In one embodiment, the image signal and the control signal may be provided to an application processor (not shown). The image signal is to be understood as a graphic source of an image to be shown in the display panel DP2. The control signal may include a synchronization signal for synchronization to output an image at an accurate location of the display panel DP2. The synchronization signal may include a vertical synchronization signal for distinguishing frames, a horizontal synchronization signal for distinguishing rows, and a data enable signal for distinguishing an output period of image data.

The timing controller TC is configured to generate an image data signal in which a data format of an image signal is converted to conform to an interface specification of the data driver DDR. The timing controller TC may generate a scan control signal to control the scan driver SDR based on a received control signal, a data control signal to control the data driver DDR, and a power control signal to control the power supply unit PSU.

The scan driver SDR may be configured to output a scan signal to the pixels PX2 through the scan lines SL based on a received scan control signal from the timing controller TC. The scan driver SDR may activate the pixels PX in units of a row.

The data driver DDR may be configured to convert the image data signal to an analog signal based on the received data control signal from the timing controller TC and output the analog-converted data signal to the pixels PX2 through the data lines DL. A luminance of light emitted by the pixels PX2 may be determined through the data signal.

The first power supply unit PSU1 may be configured to apply a driving voltage (e.g., a VDD voltage) to the power lines PL based on the power control signal, and the second power supply unit PSU2 may be configured to apply a ground voltage (e.g., a VSS voltage) to the ground line GL based on the power control signal. The pixels PX2 may be driven based on the driving voltage and the ground voltage.

FIG. 15 is an exemplary circuit diagram of the pixel shown in FIG. 14. Referring to FIG. 15, the pixel PX2 includes a scan transistor ST, a driving transistor DT, a capacitor C, and a light-emission unit LU. The light-emission unit LU corresponds to the light-emission unit LU described with reference to FIG. 1.

The scan transistor ST includes an input terminal connected to the data line DL, an output terminal connected to a gate terminal of the driving transistor DT and one end of the capacitor C, and a gate terminal connected to the scan line SL. The scan transistor ST may provide a data signal provided from the data driver DDR based on the scan signal provided from the scan driver SDR to the gate terminal of the driving transistor DT.

The driving transistor DT includes an input terminal connected to the power line PL and another end of the capacitor C, an output terminal connected to the light-emission unit LU, and a gate terminal connected to the output terminal of the scan transistor ST and one end of the capacitor C. The driving transistor DT may provide at least a portion of the driving voltage input through the power line PL based on the data signal transferred from the scan transistor ST to the light-emission unit LU.

The capacitor C is connected between the input terminal of the driving transistor DT and the gate terminal. The capacitor C may be configured to store a voltage difference between the driving voltage and the data signal to control a driving current flowing the light-emission unit LU. The light-emission unit LU may be connected between the output terminal of the driving transistor DT and the ground line GL to output light having a luminance based on the described driving current.

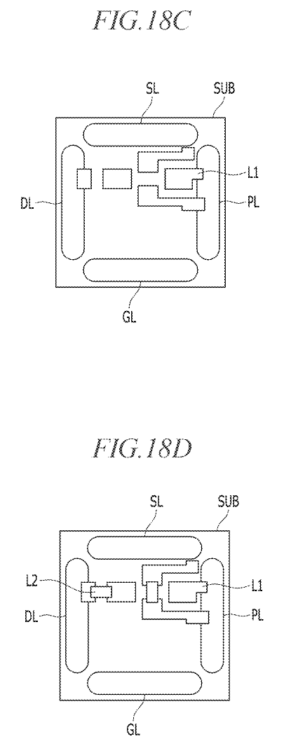

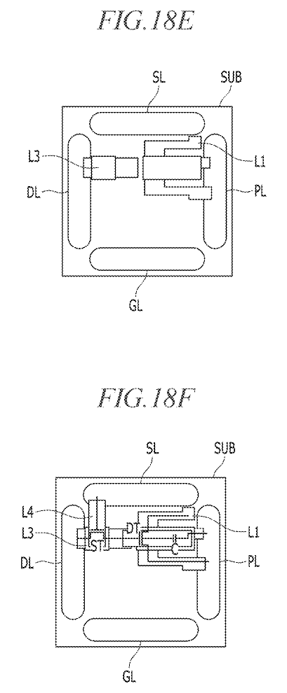

FIG. 16 is an exemplary front view of the display panel shown in FIG. 14. FIG. 17 is an exemplary rear view of the display panel shown in FIG. 14. Referring to FIG. 16 and FIG. 17, scan lines SL1 through SL4, data lines DL1 through DL4, power lines PL1 through PL4, and ground lines GL1 through GL4 (hereinafter, signal lines) are electrically connected to the pixels PX2 of the display panel DP2. The scan lines SL1 through SL4 and the ground lines GL1 through GL4 extend in the first direction DR1 and are spaced apart from one another in the second direction DR2. The data lines DL1 through DL4 and the power lines PL1 through PL4 extend in the second direction DR2 and are spaced apart from one another in the first direction DR1. Shapes of the pixels PX2 and the substrate are described with references to FIG. 2 and FIG. 3, and detailed descriptions thereof will be omitted for convenience.

Referring to FIG. 16, each of the scan lines extends in the first direction DR1 or the second direction DR2 through contact holes formed in the substrate. In one embodiment, a first data line DL1 and a first power line PL1 extend in the second direction DR2 through some of contact holes formed in pixels arranged in a first column. In one embodiment, a fourth scan line SL4 and a fourth ground line GL4 extend in the first direction DR1 through some of contact holes formed in pixels arranged in a fourth row.

The signal lines are electrically connected to the light-emission unit of the upper surface in the upper units to extend bypassing the described lower trenches. In order to prevent paths of signal lines from overlapping, eight contact holes are formed in a single upper unit. Each of the scan line, the data line, the power line, and the ground line may be electrically connected through two contact holes arranged in the extending direction in a single upper unit.

Referring to FIG. 17, each of the signal lines extends in the first direction DR1 or the second direction DR2 through contact holes formed in the substrate. The signal lines are electrically connected from a lower surface to penetrate the contact holes in the lower units to extend bypassing the described upper trenches. In one embodiment, as illustrated with a dotted line in FIG. 16, the first data line DL1 may extend in the second direction DR2 from a lower surface of the lower unit. In one embodiment, as illustrated with a dotted line in FIG. 16, a fourth scan line SL4 may extend in the first direction DR1 from a lower surface of the lower unit.

The lower unit connects adjacent upper units partitioned by the upper trenches. In the lower surfaces of the lower units, data lines DL1 through DL4 and power lines PL1 through PL4 are disposed to extend in the second direction DR2, the scan lines SL1 through SL4 and ground lines GL1 through GL4 are disposed to extend in the first direction DR1. A plurality of insulation patterns IL are disposed between the signal lines extending in the second direction DR2 and the signal lines extending in the first direction DR1. The plurality of insulation patterns IL overlap with the plurality of lower units to electrically insulate the signal lines.

Through the embodiments illustrated in FIG. 16 and FIG. 17, in a structure where a front surface and a rear surface of the substrate are partitioned by islands, wiring connections may be achieved in which paths of the data line and the scan line do not overlap and a number of contact holes is minimized.

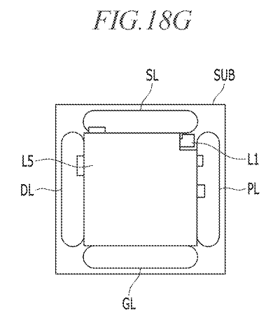

FIG. 18A through FIG. 18G are illustrations to explain a method for manufacturing the display device shown in FIG. 14. Referring to FIG. 18A, a substrate SUB where a plurality of contact holes CH are formed is provided. In one embodiment, 8 contact holes CH may be formed in a single upper unit (or island). A shape of the substrate SUB may have the shape shown in FIG. 2. At least one film may be coated, transferred, or deposited on the substrate SUB to provide planarization or to seal off the device from external substances, such as moisture or oxygen. In this case, the film may be formed through a thermal vacuum deposition method, a sputtering method, or a vapor deposition method.

Referring to FIG. 18B, a scan line SL, a data line DL, a power line PL, and a ground line GL are formed in the substrate SUB. Such signal lines may be electrically connected to the upper unit and the lower unit through the contact holes CH. One end and another end of a vertical line through the contact hole CH may be exposed on surfaces of the upper unit and the lower unit to be electrically connected to the light-emission unit LU via a contact pad. The vertical line may be formed through inkjet printing or thermal vacuum deposition methods of conductive materials such as silver nanowires (AgNW), carbon nanotubes (CNT), graphene, conductive polydimethylsiloxane (PDMS), or MXene, or metal, such as Ag, Al, Au, or Cu thin films.

Although it is not illustrated, signal lines may be formed on the lower unit using a patterned mask, as illustrated in FIG. 17. First, after the data line DL and the power line PL are formed, or after the scan line SL and the ground line GL are formed, an insulation pattern may be formed to prevent short circuits. Subsequently, a scan line SL and a ground line GL may be formed, or a data line DL and a power line PL may be formed on the insulation pattern. The signal lines and the insulation pattern may be formed through thermal vacuum deposition method or a sputtering method.

Referring to FIG. 18C, a first conductive layer L1 electrically connected to the signal lines are formed. The input terminal (source) and the output terminal (drain) of the scan transistor ST and the driving transistor DT, and one end of the capacitor C described in FIG. 15 may be formed in the upper unit using the mask. The first conductive layer L1 may be formed of a conductive material, such as copper (Cu), aluminum (Al), silver (Ag), gold (Au), nickel (Ni), and indium tin oxide (ITO), through a thermal vacuum deposition method or a sputtering method.

Referring to FIG. 18D, an activation layer L2 overlapping with at least a portion of the input terminal and the output terminal is formed. The activation layer L2 is formed between the input terminal and the output terminal using the mask. The activation layer L2 is provided as a channel of the scan transistor ST and the driving transistor DT. The activation layer L2 may be formed through a thermal vacuum deposition method or a sputtering method. The activation layer L2 may be formed of an oxide, such as indium gallium zinc oxide (IGZO) or indium tin zinc oxide (ITZO).

Referring to FIG. 18E, a first insulating layer L3 covering the activation layer L2 is formed. The first insulating layer L3 may be a gate insulating film of the scan transistor ST and the driving transistor DT as well as a dielectric of the capacitor C. The first insulating layer L3 may be formed through chemical vapor deposition (CVD) or thermal vacuum deposition. In addition, the first insulating layer L3 may be formed of an insulating oxide, such as Al2O3 or ZnO.

Referring to FIG. 18F, a second conductive layer L4 overlapping with the first insulating layer L3 and the activation layer L2 and electrically connected to at least a portion of the signal lines is formed. The gate terminal of the scan transistor ST and the driving transistor DT and another end of the capacitor C may be formed using a mask. The second conductive layer L4 may be formed through a thermal vacuum deposition method or a sputtering method. The second conductive layer L4 may be formed of a conductive material, such as copper (Cu), aluminum (Al), silver (Ag), gold (Au), nickel (Ni), and indium tin oxide (ITO), through a thermal vacuum deposition method or a sputtering method. As a result, a backplane circuit of the pixel PX2 described in FIG. 15 may be implemented.

Referring to FIG. 18G, the second insulating layer L5 may be formed on the first conductive layer L1, the activation layer L2, the first insulating layer L3, and the second conductive layer L4. The second insulating layer L5 may be formed to provide electrical shielding between the light-emission unit LU and the backplane circuit. Here, the second insulating layer L5 may be patterned to have a drain portion of the driving transistor DT exposed and electrically connected to an anode electrode of the light-emission unit LU. The second insulating layer L5 may be formed through a chemical vapor deposition (CVD) method or a thermal vacuum deposition method. In addition, the second insulating layer L5 may be formed of an insulating oxide, such as Al2O3 or ZnO.

Subsequently, a light-emission unit LU may be formed on the second insulating layer L5. The structure of the light-emission unit LU is described above with reference to FIG. 13, and therefore, will be omitted. The cathode electrode CA is to be understood to be connected to the ground line GL, and the anode electrode AN is to be understood to be connected to the first conductive layer L1. Furthermore, although it is not illustrated, the light-emission unit LU may further include a hole control layer, such as a hole transport layer (HTL) and a hole injection layer (HIL) between the light-emission layer LL and the anode electrode AN. Although it is not illustrated, the light-emission unit LU may further include an electron control layer, such as an electron transport layer (ETL) and an electron injection layer (EIL) between the light-emission layer LL and the cathode electrode CA.

Meanwhile, in one embodiment, formation of the active layer is exemplified after the formation of source/drain layers for manufacture of the thin-film transistor, but the present disclosure is not limited thereto. Nonetheless, it will be apparent to those skilled in the art that the source/drain layers can be formed after the formation of the active layer. In addition, in one embodiment, a method of manufacturing a top-gate thin-film transistor is exemplified, but the present disclosure is not limited thereto. It will be apparent to those skilled in the art that a thin film transistor of a bottom-gate type can be manufactured.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display panel comprising:
a substrate comprising a plurality of upper units arranged two-dimensionally on a plane and separated by upper trenches, a plurality of lower units arranged two-dimensionally on a plane and separated by lower trenches, and a plurality of pillar units connecting, in a thickness direction, one of the plurality of upper units and one of the plurality of lower units; and
a plurality of light-emission units disposed on the plurality of upper units and arranged two-dimensionally,
wherein each of the plurality of upper units is connected to at least two pillar units, each of the plurality of lower units is connected to at least two pillar units, and pillar units extending from one upper unit among the plurality of upper units are respectively connected to different lower units among the plurality of lower units.

2. The display panel of claim 1,
wherein the upper trenches overlaps with the plurality of lower units while not overlapping with the plurality of upper units and the plurality of pillar units in a planar view, and
wherein the lower trenches overlaps with the plurality of upper units while not overlapping with the plurality of lower units and the plurality of pillar units in a planar view.

3. The display panel of claim 1,
wherein each of the plurality of upper units is partitioned in a second direction intersecting with a first direction by first upper trenches extending in the first direction, and is partitioned in the first direction through second upper trenches extending in the second direction, and
wherein each of the plurality of lower units is partitioned in the second direction by first lower trenches extending in the first direction, and is partitioned in the first direction by second lower trenches extending in the second direction.

4. The display panel of claim 3,
wherein the first upper trenches do not overlap with the first lower trenches, and the second upper trenches do not overlap with the second lower trenches.

5. The display panel of claim 1,
wherein each of the plurality of upper units overlaps with at least two lower units among the plurality of lower units, and at least two pillar units among the plurality of pillar units, and is connected to the overlapping lower units through the overlapping pillar units.

6. The display panel of claim 5,
wherein each of the plurality of upper units is connected to four lower units through four pillar units, and
wherein each of the plurality of lower units is connected to four upper units through four pillar units.

7. The display panel of claim 1,
wherein respective cross-sectional areas of the plurality of pillar units in a planar view are smaller than an area of one upper unit divided by a number of pillar units connected to the upper units.

8. The display panel of claim 1,
wherein respective thicknesses of the plurality of pillar units are greater than thicknesses of the plurality of upper units or thicknesses of the plurality of lower units.

9. The display panel of claim 1,
wherein a plurality of contact holes penetrating the plurality of pillar units, respectively, in the thickness directions are formed, and
wherein the plurality of contact holes further penetrate the plurality of upper units and the plurality of lower units overlapping in the thickness directions.

10. The display panel of claim 9,
wherein lines electrically connected to the plurality of light-emission units are provided in the plurality of contact holes, and the lines provided in the plurality of contact holes are electrically connected through lower surfaces of the plurality of lower units.

11. The display panel of claim 9, further comprising:
scan lines provided in first contact holes among the plurality of contact holes and electrically connected to light-emission units arranged in a first direction; and
data lines provided in second contact holes different from the first contact holes among the plurality of contact holes and electrically connected to light-emission units arranged in a second direction intersecting with the first direction.

12. The display panel of claim 11,
wherein the scan lines extending in the first direction are disposed on lower surfaces of the first lower units, where the first contact holes are formed, among the plurality of lower units,
wherein the data lines extending in the second direction are disposed on lower surfaces of the second lower units, where the second contact holes are formed, among the plurality of lower units, and
wherein the first lower units and the second lower units are alternatingly arranged in the first direction and the second direction.

13. The display panel of claim 11, further comprising:
power supply lines provided in third contact holes different from the first contact holes and the second contact holes among the plurality of contact holes and electrically connected to light-emission units arranged in the first direction or the second direction.

14. The display panel of claim 11,
wherein the scan lines extending in the first direction and the data lines extending in the second direction are disposed on lower surfaces of the plurality of lower units, and
wherein the display panel further comprises a plurality of insulation patterns disposed between the scan lines and the data lines and overlapping with the plurality of lower units.

15. A display device comprising:
a display panel with pixels connected to a scan line and a data line and arranged two-dimensionally; and
a driving circuit configured to control operation of the pixels through the scan line and the data line to display an image,
wherein the display panel comprises:
a substrate comprising a plurality of upper units arranged two-dimensionally on a plane and separated by upper trenches, a plurality of lower units arranged two-dimensionally on a plane and separated by lower trenches, and a plurality of pillar units connecting one of the plurality of upper units and one of the plurality of lower units in a thickness direction; and
a plurality of light-emission units disposed on the plurality of upper units and corresponding to the pixels, and
wherein each of the plurality of upper units is connected to at least two pillar units, each of the plurality of lower units is connected to at least two pillar units, and each of pillar units extending from one upper unit among the plurality of upper units is connected to different lower units among the plurality of lower units.

16. The display device of claim 15,
wherein a plurality of contact holes respectively penetrating the plurality of pillar units in thickness directions are formed on the substrate,
wherein the plurality of contact holes further penetrate the plurality of upper units and the plurality of lower units facing each other in the thickness direction,
wherein the scan line is provided in first contact holes among the plurality of contact holes, and
wherein the data line is provided to the second contact holes among the plurality of contact holes.

17. The display device of claim 15,
wherein the driving circuit is configured to control a potential between the data line and the scan line to activate pixels for displaying an image.

18. The display device of claim 16,
wherein the driving circuit comprises:
a data driver configured to output a data signal to the pixels through the data line;
a scan driver configured to sequentially activate the pixels to display an image according to the data signal through the scan line; and
a timing controller configured to control the data driver and the scan driver.

19. A method for manufacturing a display device, the method comprising:
providing a substrate, the substrate comprising a plurality of upper units arranged two-dimensionally on a plane and separated by upper trenches, a plurality of lower units arranged two-dimensionally on a plane and separated by lower trenches, and a plurality of pillar units connecting one of the plurality of upper units and one of the plurality of lower units in a thickness direction and having a plurality of contact holes formed therein;
forming signal lines on the plurality of contact holes, the plurality of upper units, and the plurality of lower units; and
forming a plurality of light-emission units on the signal lines and the plurality of the upper units,
wherein each of the plurality of upper units is connected to at least two pillar units, each of the plurality of lower units is connected to at least two pillar units, and each of pillar units extending from one upper unit among the plurality of upper units are respectively connected to different lower units among the plurality of lower units, and
wherein the plurality of contact holes further penetrate the plurality of upper units and the plurality of lower units overlapping in the thickness direction.

20. The method for manufacturing a display device of claim 19, the method further comprising:
after the forming the signal lines,
forming a first conductive layer electrically connected to at least a portion of the signal lines;
forming an activation layer overlapping with at least a portion of the first conductive layer;
forming a first insulating layer covering the activation layer;
forming a second conductive layer overlapping with the first insulating layer and the activation layer and electrically connected to at least a portion of the signal lines; and
forming a second insulating layer on the first conductive layer, the activation layer, the first insulating layer, and the second conductive layer.
